(19) United States
(12) Patent Application Publication
(10) Pub. No.: US 2023/0107596 A1
(43) Pub. Date: Apr. 6, 2023

(54) LIQUID-COOLED NOTEBOOK COMPUTER AND POWER SUPPLY DEVICE THEREOF

(71) Applicant: Uniwill Technology Inc., Taipei (TW)

(72) Inventors: Chih-Hsien CHEN, Taipei (TW); Pon-Chung CHIEN, Taipei (TW); Yu-Cheng SHIH, Taipei (TW)

(21) Appl. No.: 17/834,060

(22) Filed: Jun. 7, 2022

(30) Foreign Application Priority Data
Oct. 6, 2021 (TW) 110211760

(51) Int. Cl. G06F 1/20; G06F 1/26; H05K 7/20

(52) U.S. Cl. CPC G06F 1/203; G06F 1/26; H05K 7/20154; H05K 7/20263; H05K 7/20272

(57) ABSTRACT

Liquid-cooled notebook computer and power supply device thereof, includes a power supply line set including AC power supply line, transformer device set in adapter and electrically connected to AC power supply line and DC power supply line electrically connected to the other side of transformer device, a water cooling device installed in adapter, and a notebook computer with infusion inlet and infusion outlet thereof respectively connected to water outlet and water inlet of water cooling device. The infusion inlet and the infusion outlet are connected to the internal chip surface of notebook computer through infusion pipeline, and a heat conduction source is attached to the chip surface. After the water pump in water cooling device is actuated, the heat conduction source transports the heat generated by the chip from the notebook computer to water cooling device for circulating exchange of cold and hot liquids for heat dissipation.

This application claims the priority benefit of Taiwan Patent Application Number 110211760, filed on Oct. 6, 2021.

### BACKGROUND OF THE INVENTION

### 1. Field of the Invention

The present invention provides a liquid-cooled notebook computer and a power supply device thereof, especially a structure in which the water cooling device is combined with the adapter of the power supply line set, and the water cooling device can be movably connected to the notebook computer, and can circulate and exchange cold and hot liquids for the chip to dissipate heat.

### 2. Description of the Related Art

Nowadays, more and more users choose to replace traditional desktop computers with notebook computers due to the convenience of carrying them around and the advantages of not occupying space. The general notebook computer needs to move towards the trend of light, thin, short and small in design, so the electronic components or devices inside the notebook computer are very crowded in arrangement. Although notebook computers are equipped with fans or heat pipe liquid-gas exchange equipment to assist heat dissipation, the cooling efficiency that fans or heat pipe liquid-gas exchange equipment can achieve in a limited space is obviously insufficient. If you want to provide enough heat dissipation efficiency, the structure will occupy a huge space inside the notebook. When the heat dissipation structure increases enough heat dissipation efficiency, its overall weight and structural arrangement will also increase. In a notebook computer with limited space, it is very likely that due to the influence of weight and the structural complexity of the combination, the heat dissipation structure of the notebook computer may be displaced during the transportation process and may hit other electronic components after the displacement, which will damage the notebook computer or cause a short circuit. Moreover, this move also violates the lightweight and ultra-thin design requirements of notebook computers. Furthermore, the current home economy is prevalent, so the game industry and the audio-visual industry are booming. However, because notebook computers are limited by volume and weight issues, the resulting heat dissipation and performance-related power supply wattage (overclocking) problems. As we all know, the power supply line set of a notebook computer includes an AC power supply line, a transformer device that is electrically connected to the AC power supply line, and a DC power supply line that is electrically connected to the transformer device. The transformer device is set in the adapter. However, there are also manufacturers’ designs today, which are to carry the water cooling device on the top of the screen to enhance the cooling effect of the notebook computer. This method can only be used in a fixed location, which is not conducive to the user’s carrying and use, and the notebook computer, power supply line set and water cooling device are not only unfavorable to carry, and the water cooling device is also easily damaged by impact. Therefore, how to improve the above-mentioned deficiencies, reduce the weight and volume and increase the heat dissipation efficiency at the same time, is the key point for those engaged in this industry to improve.

Therefore, in view of the above-mentioned problems and deficiencies, the inventor collects relevant information, evaluates and considers from various parties, and designs this liquid-cooled notebook computer and power supply device thereof with years of accumulated experience in this industry and continuous modification.

### SUMMARY OF THE INVENTION

The present invention has been accomplished under the circumstances in view. It is therefore the main object of the present invention to install a water cooling device and a transformer device at the adapter of the notebook computer’s power supply line set, wherein the transformer device in the adapter is electrically connected to the AC power supply line of the mains socket and the DC power supply line of the notebook computer power socket respectively; the water outlet and water inlet of the water cooling device are connected to the infusion inlet and infusion outlet of the notebook computer through connecting pipes; the infusion inlet and the infusion outlet are connected to the internal chip surface of the notebook computer through the infusion pipeline, and a heat conduction source is attached to the chip surface, so that after the water pump in the water cooling device is actuated, the heat conduction source transports the heat generated by the chip from the notebook computer to the water cooling device for circulating exchange of cold and hot liquids for heat dissipation. In this way, it is easy to maintain, easy to carry, and can be used according to the actual needs of users.

Another object of the present invention is to install a water cooling device and a transformer device at the adapter of the power supply line set used by the notebook computer, wherein the transformer device in the adapter is equipped with AC power supply line and DC power supply line respectively, and the water outlet and water inlet of the water cooling device can form active connections with the infusion inlet, heat conduction source and infusion outlet of the preset notebook computer, so that after the water pump in the water cooling device is activated, the chip of the preset notebook computer can be used to exchange cold and hot liquid for heat dissipation, so as to achieve simple maintenance, easy portability, and function selections according to the actual needs of users.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a three-dimensional external view of a preferred embodiment of the present invention.

FIG. 2 is an oblique top elevational view of the power supply line set and the water cooling device according to the preferred embodiment of the present invention.

FIG. 3 corresponds to FIG. 2 when viewed from another angle.

FIG. 4 is an exploded view of the power supply line set and the water cooling device according to the preferred embodiment of the present invention.

FIG. 5 corresponds to FIG. 4 when viewed from another angle.

FIG. 6 is a three-dimensional schematic diagram of the preferred embodiment of the present invention.

### DETAILED DESCRIPTION OF THE PREFERRED EMBODIMENT

In order to achieve the above-mentioned objects and effect, the technical means used in the present invention and its structure are hereby described in detail with reference to the preferred embodiment of the present invention, and its features and functions are as follows, so as to be fully understood.

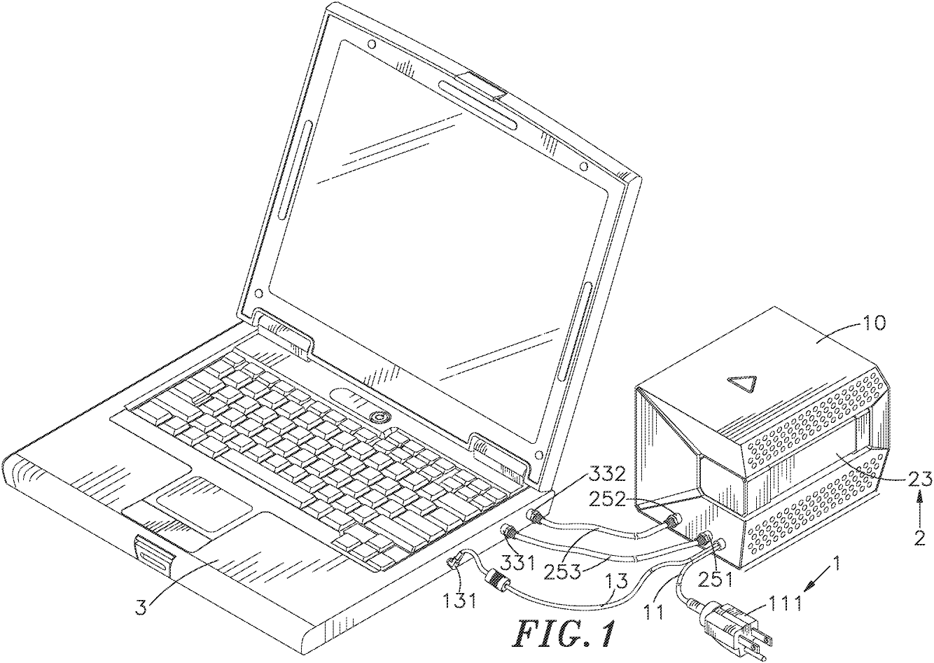

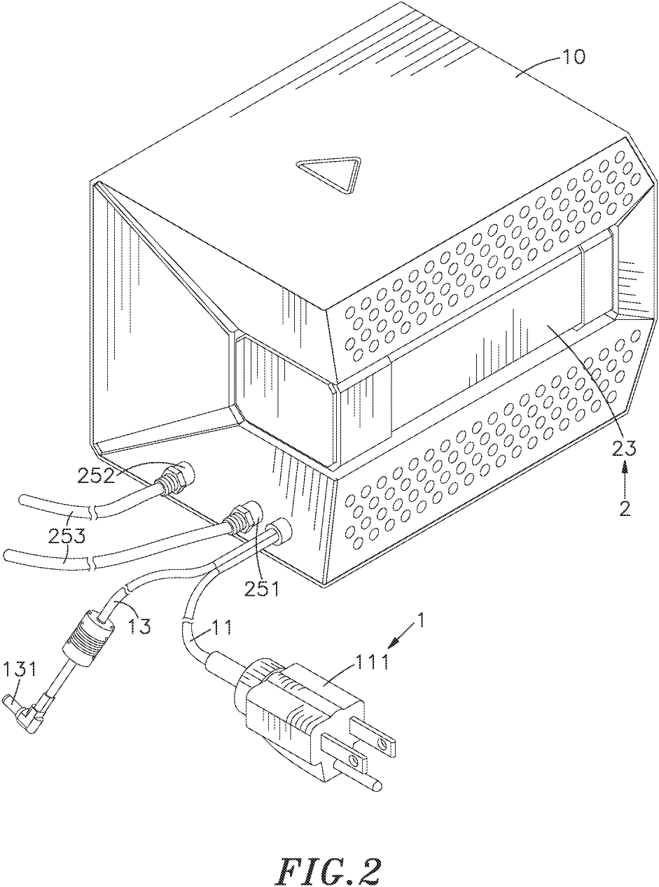

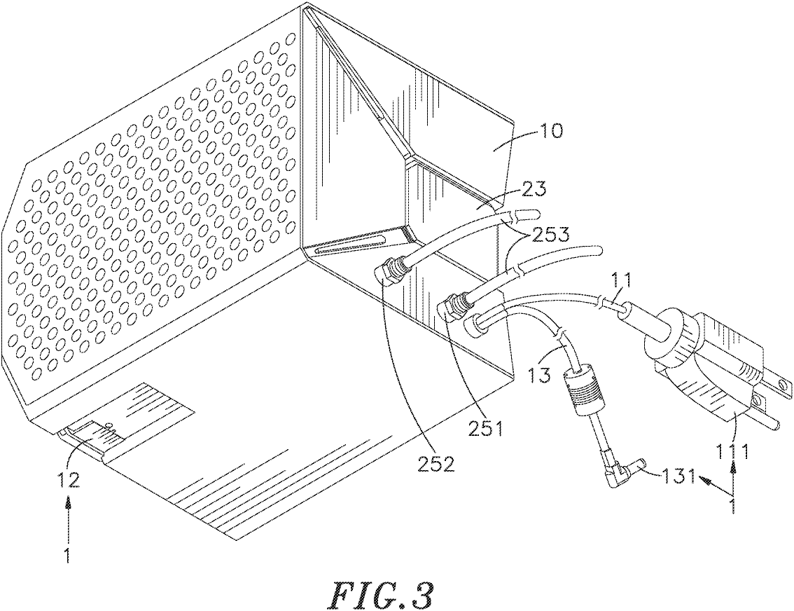

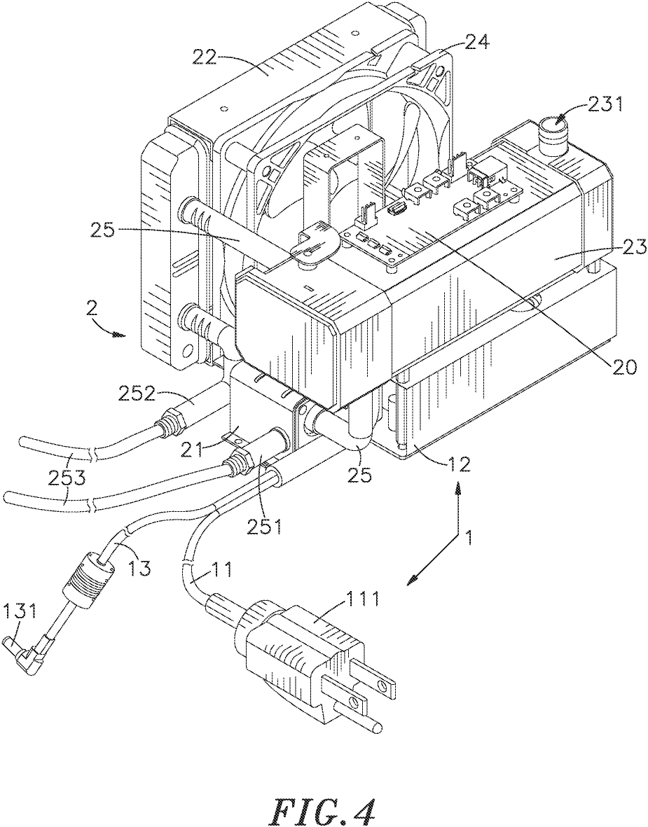

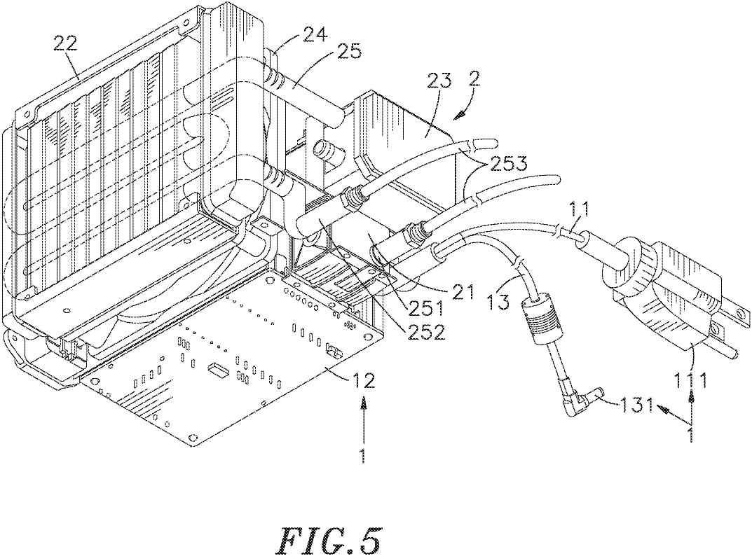

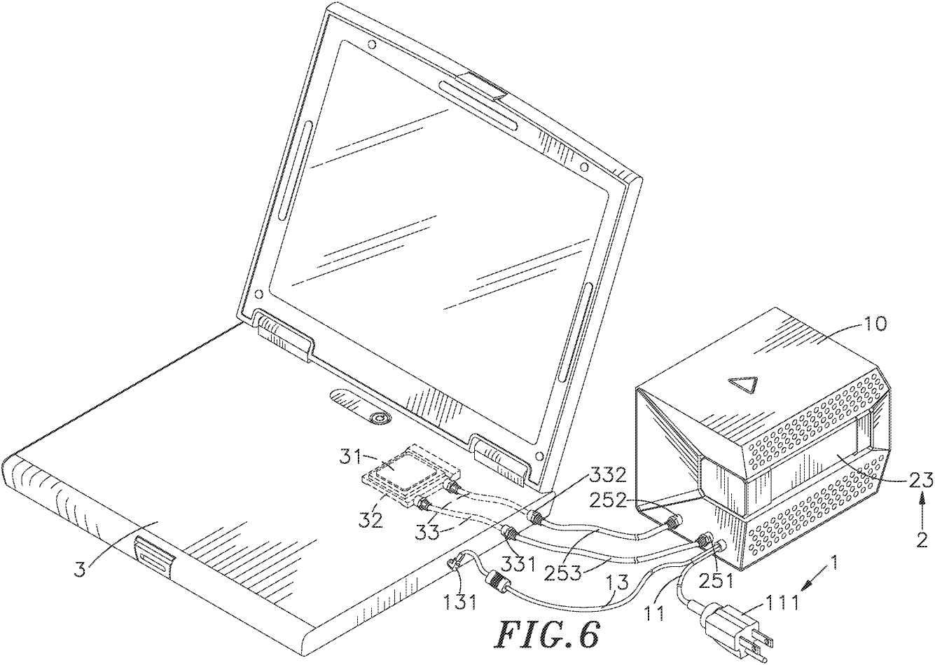

Please refer to FIGS. 1-6, where FIG. 1 is a three-dimensional external view of a preferred embodiment of the present invention; FIG. 2 is an oblique top elevational view of the power supply line set and the water cooling device according to the preferred embodiment of the present invention; FIG. 3 corresponds to FIG. 2 when viewed from another angle; FIG. 4 is an exploded view of the power supply line set and the water cooling device according to the preferred embodiment of the present invention; FIG. 5 corresponds to FIG. 4 when viewed from another angle; FIG. 6 is a three-dimensional schematic diagram of the preferred embodiment of the present invention. It can be clearly seen from the figure that the present invention comprises a power supply line set 1, a water cooling device 2 and a notebook computer 3.

The power supply line set 1 comprises an AC power supply line 11, a transformer device 12 in an adapter 10 to which the AC power supply line 11 is electrically connected, and a DC power supply line 13 that is electrically connected to the other side of the transformer device 12. The end of the AC power supply line 11 is provided with an AC plug 111 that can be plugged into the mains socket. The end of the DC power supply line 13 is provided with a DC plug 131 that can be plugged into the power socket of the notebook computer 3.

The water cooling device 2 is installed in the adapter 10. A water outlet 251 and a water inlet 252 of the water cooling device 2 are respectively connected to an infusion inlet 331 and an infusion outlet 332 of the notebook computer 3. The water cooling device 2 comprises a control circuit board 20 electrically connected to the transformer device 12, a water pump 21 electrically connected to the control circuit board 20 and powered by the transformer device 12 through the control circuit board 20, a water cooling row 22 with a plurality of cooling fins, a transparent or translucent water tank 23, and a cooling fan 24 electrically connected to the control circuit board 2. The water tank 23 is provided with a water injection port 231. The water inlet 252 passes through the outside of the adapter 10 and is arranged on one side of the water cooling row 22. The water cooling row 22 is further connected to the water tank 23 and the water pump 21 by a water delivery pipeline 25 in sequence. The water pump 21 is provided with the water outlet 251 outside the adapter 10. The water outlet 251 and the water inlet 252 of the water cooling device 2 can form active connections with the infusion inlet 331 and the infusion outlet 332 of the notebook computer 3 through connecting pipes 253.

The surface of the internal chip 31 of the notebook computer 3 is attached with a heat conduction source 32, and the heat conduction source 32 is connected to the infusion inlet 331 and the infusion outlet 332 outside the notebook computer 3 through at least two infusion pipelines 33.

Referring to FIGS. 1-6 again, in the present invention, when the water pump 21 is actuated, the water or liquid is pushed from the water tank 23 to the infusion inlet 331 of the notebook computer 3 through the water delivery pipeline 25, the water outlet 251 and the connecting pipes 253, so that water or liquid is sequentially entered from the infusion pipeline 33 into the inner surface of the heat conduction source 32 to absorb heat, and the high heat generated by the chip 31 is transferred to the infusion outlet 332 of the notebook computer 3 by the infusion pipeline 33 at the other side of the heat conduction source 32. The endothermic water or liquid is transported to the water cooling row 22 through the connecting pipes 253 towards the water inlet 252 of the water cooling device 2. At this time, the cooling fan 24 is used to blow the water cooling row 22 outward to dissipate heat. Continue to make the heat-dissipated water or liquid enter the water tank 23 from the water delivery pipeline 25. In this way, the chip 31 of notebook computer 3 can be efficiently dissipated in a cycle.

The water cooling row 22 of the present invention can also be provided with fins for heat dissipation or other structures that can increase the heat dissipation area (not shown), so that after the heat-absorbing water or liquid enters the water cooling row 22, the cooling fan 24 blows it toward the outside of the water cooling row 22 for heat dissipation. The heat-dissipated water or liquid then enters the water tank 23 through the water delivery pipeline 25, and is then actuated by the water pump 21 to repeat the above-mentioned circulating heat dissipation of the heat source of the chip 31.

The chip 31 of the present invention can be a central processing unit (CPU), a graphics processing unit (GPU), or other components that generate high heat during operation. The chip 31 and the heat conduction source 32 can be fixed by mechanical components, and can be further coated with thermal conductive paste, thermal conductive patch or a phase change material for thermal conduction. Such simple structural changes should be included in the scope of the patent covered by the present invention, such as the equivalent changes accomplished without departing from the technical spirit disclosed in the present invention.

The present invention can also be further provided with a connector or its module (not shown) at the adapter 10 of the power supply line set 1, such as a USB, a network connection or an audio-visual input and output device (not shown), and the transformer device 12 provides it with the necessary power supply. This is a conventional technology that generally exists in the market and will not be repeated here. Therefore, such simple structural changes, such as equivalent changes completed without departing from the technical spirit disclosed in the present invention, all should be included in the scope of the patent covered by the present invention.

The water or liquid of the present invention can be reverse osmosis pure water, water with appropriate additives (such as anti-corrosion agents and anti-freezing agents, etc.) or other liquids that improve thermal conductivity. Such simple structural changes should be included in the scope of the patent covered by the present invention, such as the equivalent changes accomplished without departing from the technical spirit disclosed in the present invention.

The water cooling device 2 of the present invention is combined with the structural design of the power supply line set 1. A separate assembly positioning structure design (not shown) can also be used. Such simple structural changes should be included in the scope of the patent covered by the present invention, such as the equivalent changes accomplished without departing from the technical spirit disclosed in the present invention.

The advantages of the present invention are:
(1) The water cooling device 2 of the present invention is combined with the adapter 10 of the power supply line set 1 to form a positioning, wherein the connecting pipes of the water outlet 251 and the water inlet 252 of the water cooling device 2 and the power supply lines can be carried at the same time and connected to the power socket, the infusion inlet 331 and the infusion outlet 332 of the notebook computer 3. Therefore, when the user has high-level graphics, video playback, games, etc. that will cause the chip 31 to generate high heat, carrying the power supply line set 1 with the water cooling device 2 can effectively solve the problem of forgetting and falling when the user is carrying it. However, when the user does not have the operation requirements for high-level drawing, video and audio playback, and playing games, the user can also carry the general power supply line set for use.
(2) When the water cooling device 2 of the present invention is combined with the power supply line set 1 and positioned as a whole, the user can know the amount of water through the transparent or translucent water tank 23, and when the water is insufficient, the user can simply inject water from the water injection port 231, so as to achieve the purpose of convenient maintenance.
(3) When the water cooling device 2 of the present invention is combined with the power supply line set 1 to form an integral body, the adapter 10 with the water cooling device 2 is equipped with connectors such as USB, network connection, hub, audio-visual input and output devices, etc. or its modules. Users can decide to purchase a power supply line set 1 with special functions. Whether a cooling fan 24, a water return device or other additional functions are required to be installed in the water cooling device 2, the user can also decide which optional components to purchase for the notebook computer 3.

The above detailed description is only for describing a preferred feasible embodiment of the present invention, but the embodiment is not intended to limit the scope of the patent application of the present invention. All other equivalent changes and modifications accomplished without departing from the technical spirit disclosed in the present invention shall be included in the scope of the patent covered by the present invention.

What the invention claimed is:

1. A liquid-cooled notebook computer, comprising a power supply line set, a water cooling device and a notebook computer, wherein:
said power supply line set comprises an AC power supply line, an adapter, a transformer device set in said adapter and electrically connected with one side thereof to said AC power supply line, and a DC power supply line electrically connected to an opposite side of said transformer device, said DC power supply line being electrically connected to said notebook computer;
said water cooling device is installed in said adapter, said water cooling device comprising a water outlet and a water inlet
said notebook computer comprises an infusion inlet and an infusion outlet respectively connected to said water outlet and said water inlet of said water cooling device by connecting pipes, a plurality of infusion pipelines, a chip, a heat conduction source attached to a surface of said chip and connected to said infusion inlet and said infusion outlet through said infusion pipelines, so that after a water pump in said water cooling device is activated, the heat generated by said chip is circulated and exchanged for heat dissipation.

2. The liquid-cooled notebook computer as claimed in claim 1, wherein said water cooling device comprises said water pump, a water cooling row and a water tank, said water cooling row having one side thereof provided with said water inlet extended outside said adapter and connected to said infusion outlet of said notebook computer, said water cooling row being connected to said water tank and said water pump in sequence with a water delivery pipeline, said water pump being provided with said water outlet extended outside said adapter.

3. The liquid-cooled notebook computer as claimed in claim 2, wherein said water cooling device further comprises a cooling fan located at an inner side relative to said water cooling row for blowing air to the outside for heat dissipation.

4. The liquid-cooled notebook computer as claimed in claim 1, wherein said water cooling device further comprises a control circuit board electrically connected to said transformer device, and said water pump is electrically connected to said control circuit board and powered by said transformer device through said control circuit board.

5. A power supply device for notebook computer, comprising a power supply line set and a water cooling device, wherein:
said power supply line set comprises an AC power supply line, an adapter, a transformer device set in said adapter and electrically connected with one side thereof to said AC power supply line, and a DC power supply line electrically connected to an opposite side of said transformer device;
said water cooling device is installed in said adapter, said water cooling device comprising a water outlet and a water inlet respectively connected to an infusion inlet and an infusion outlet of a preset notebook computer with connecting pipes.

6. The power supply device for notebook computer as claimed in claim 5, wherein said water cooling device comprises a water pump, a water cooling row and a water tank, said water cooling row having one side thereof provided with said water inlet extended outside said adapter and connected to said infusion outlet of said notebook computer, said water cooling row being connected to said water tank and said water pump in sequence with a water delivery pipeline, said water pump being provided with said water outlet extended outside said adapter.

7. The power supply device for notebook computer as claimed in claim 6, wherein said water cooling device further comprises a cooling fan located at an inner side relative to said water cooling row for blowing air to the outside for heat dissipation.

8. The power supply device for notebook computer as claimed in claim 5, wherein said water cooling device further comprises a control circuit board installed in said adapter; said water pump is electrically connected to said control circuit board and powered by said control circuit board.
